(19) United States
(12) Patent Application Publication
(10) Pub. No.: US 2022/0157827 A1
(43) Pub. Date: May 19, 2022

(54) SEMICONDUCTOR STRUCTURE AND MANUFACTURING METHOD THEREFOR, AND STORAGE DEVICE

(71) Applicant: CHANGXIN MEMORY TECHNOLOGIES, INC., Hefei City (CN)

(72) Inventors: Xing JIN, Hefei City (CN); Zhengqing SUN, Hefei City (CN); Ming CHENG, Hefei City (CN); Ran LI, Hefei City (CN)

(73) Assignee: CHANGXIN MEMORY TECHNOLOGIES, INC., Hefei City (CN)

(21) Appl. No.: 17/649,187

(22) Filed: Jan. 27, 2022

Related U.S. Application Data
(63) Continuation of application No. PCT/CN2021/109059, filed on Jul. 28, 2021.

(30) Foreign Application Priority Data
Sep. 27, 2020 (CN) 202011034963.5

(51) Int. Cl. H01L 27/108

(52) U.S. Cl. CPC H01L 27/10885; H01L 27/10855

(57) ABSTRACT

A manufacturing method for a semiconductor structure includes: a semiconductor substrate is provided, the semiconductor substrate includes multiple first regions and second regions which are alternately disposed; multiple bitline structures are formed on the semiconductor substrate, any one of the bitline structures penetrates through the first regions and the second regions; the bitline structures in the first regions are etched, to enable each sidewall on two sides of each of the bitline structure to be in a step shape; and multiple electrode structures are formed, any one of the electrode structures includes a conductive plug and a contact pad in mutually electric connection, and each conductive plug is disposed at a respective first region, disposed between two neighboring bitline structures and connected to the semiconductor substrate.

### CROSS-REFERENCE TO RELATED APPLICATIONS

This application is a continuation of International Application No. PCT/CN2021/109059 filed on Jul. 28, 2021, which claims priority to Chinese Patent Application No. 202011034963.5 filed on Sep. 27, 2020. The disclosures of these applications are hereby incorporated by reference in their entirety.

### BACKGROUND

A dynamic random-access memory (DRAM) may include a sunken transistor array layer, a wiring layer and a capacitance layer disposed in a stack. The wiring layer includes a bitline structure, a conductive plug and a contact pad. The bit line structure is electrically connected to a source of a sunken transistor; a capacitance contact hole isolated by a dielectric barricade is included between two neighboring bitline structures; the capacitance contact hole is filled with the conductive plug to be connected to a drain of the sunken transistor; and the contact pad is connected on a side of the conductive plug away from the sunken transistor array layer to be electrically connected to a capacitor.

The information disclosed above by the background art is merely used for enhancing the understanding of the background of this disclosure and therefore, it may include information of the prior art known by a person having ordinary skill in the art.

### SUMMARY

This disclosure relates to the technical field of semiconductors, and in particular, to a semiconductor structure and a manufacturing method therefor, and a storage device.

The purpose of this disclosure is to provide a semiconductor structure and a manufacturing method therefor, and a storage device, and to improve the yield of the semiconductor structure.

To achieve the purpose above, this disclosure adopts the following technical solution.

According to a first aspect of this disclosure, provided is a manufacturing method for a semiconductor structure, including:

a semiconductor substrate is provided, the semiconductor substrate includes multiple first regions and second regions which are alternately disposed;

multiple bitline structures are formed on the semiconductor substrate, any one of the bitline structures penetrates through the first regions and the second regions;

the bitline structures are etched in the first regions, to enable each sidewall on two sides of each of the bitline structure to be in a step shape; and

multiple electrode structures are formed, any one of the electrode structures includes a conductive plug and a contact pad in mutually electric connection and each conductive plug is disposed at a respective first region, disposed between two neighboring bitline structures and connected to the semiconductor substrate.

According to a second aspect of this disclosure, provided is a semiconductor structure, including:

a semiconductor substrate, the semiconductor substrate includes multiple first regions and second regions which are alternately disposed;

multiple bitline structures, any one of the bitline structures penetrates through the first regions and the second regions; and in the first regions, each sidewalls on two sides of each of the bitline structure is in a step shape; and

multiple electrode structures, any one of the electrode structures includes a conductive plug and a contact pad in mutually electric connection and each conductive plug is disposed at a respective first region, disposed between two neighboring bitline structures and connected to the semiconductor substrate.

According to a third aspect of this disclosure, provided is a storage device including the semiconductor structure.

### BRIEF DESCRIPTION OF THE DRAWINGS

By describing exemplary embodiments thereof in detail with reference to the accompanying drawings, the aforementioned and other features and advantages of this disclosure would become more obvious.

FIG. 1 is an electron micrograph of a cross-section of a wiring layer in some implementations.

FIG. 2 is an electron micrograph taken in top view of a wiring layer in some implementations.

FIG. 3 is a flowchart of a manufacturing process of a semiconductor structure according to an embodiment of the present disclosure.

FIG. 4 is a top view of structural schematic diagram of a semiconductor substrate according to an embodiment of the present disclosure.

FIG. 5 is a section view of structural schematic diagram of a semiconductor substrate according to an embodiment of the present disclosure.

FIG. 6 is a structural schematic diagram of a bitline contact trench formed according to an embodiment of the present disclosure.

FIG. 7 is a structural schematic diagram of conductive material layer and dielectric material layer formed according to an embodiment of the present disclosure.

FIG. 8 is a structural schematic diagram of a bitline lead formed according to an embodiment of the present disclosure.

FIG. 9 is a top view of structural schematic diagram of a bitline lead formed according to an embodiment of the present disclosure.

FIG. 10 is a structural schematic diagram of a dielectric sidewall formed according to an embodiment of the present disclosure.

FIG. 11 is a structural schematic diagram of a sacrificial dielectric layer formed according to an embodiment of the present disclosure.

FIG. 12 is a three-dimensional structural schematic diagram of a dielectric barricade formed according to an embodiment of the present disclosure.

FIG. 13 is a three-dimensional structural schematic diagram after the bitline structure is etched for the first time in a first region according to an embodiment of the present disclosure.

FIG. 14 is a three-dimensional structural schematic diagram after the bitline structure is etched for the second time at the first region according to an embodiment of the present disclosure.

FIG. 15 is a three-dimensional structural schematic diagram of a plug material layer formed according to an embodiment of the present disclosure.

FIG. 16 is a section view of structural schematic diagram of a plug material layer formed according to an embodiment of the present disclosure, and a section direction is parallel to a word line direction.

FIG. 17 is a top view of structural schematic diagram of a d plug material layer formed according to an embodiment of the present disclosure.

FIG. 18 is a three-dimensional structural schematic diagram of a contact pad material layer formed according to an embodiment of the present disclosure.

FIG. 19 is a section view of structural schematic diagram of a contact pad material layer formed according to an embodiment of the present disclosure.

FIG. 20 is a section view of structural schematic diagram of a second mask structure formed according to an embodiment of the present disclosure.

FIG. 21 is a section view of structural schematic diagram of a electrode structure formed according to an embodiment of the present disclosure.

Reference numerals of main components in the drawings are explained as follows:

100, semiconductor substrate; 110, active region; 120, shallow trench isolation structure; 130, gate dielectric layer; 140, wordline; 150, dielectric top cover; 200, bitline structure; 201, conductive material layer; 2011, first conductive material layer; 2012, second conductive material layer; 2013, third conductive material layer; 202, dielectric material layer; 2021, first dielectric material layer; 2022, second dielectric material layer; 203, dielectric sidewall material layer; 2031, first dielectric sidewall material layer; 2032, second dielectric sidewall material layer; 210, bitline lead; 211, conductive lead; 2111, first conductive lead layer; 2112, second conductive lead layer; 2113, third conductive lead layer; 212, dielectric protection layer; 2121, first dielectric protection layer; 2122, second dielectric protection layer; 220, dielectric sidewall; 221, first dielectric sidewall; 222, second dielectric sidewall; 230, bitline contact trench; 300, electrode structure; 310, conductive plug; 311, plug material layer; 3111, polycrystalline silicon layer; 3112, metal layer; 320, contact pad; 321, contact pad material layer; 330, capacitance contact hole; 340, second mask structure; 350, isolation grooves; 410, sacrificial dielectric layer; 420, dielectric barricade; 430, first mask structure; A, first region; and B, second region.

### DETAILED DESCRIPTION

Exemplary embodiments are described more fully now with reference to the accompanying drawings. However, the exemplary embodiments can be implemented in multiple forms, an cannot be understood as to be limited to the examples elaborated herein. On the contrary, providing these embodiments enables this disclosure to be more comprehensive, and enables complete concept of the exemplary embodiments to be comprehensively delivered to a person skilled in the art. The features, structures, or characteristics described above can be combined into one or more embodiments in any proper mode. In the description below, many specific details are provided to provide full understanding of the embodiments of this disclosure.

In the drawings, for clarity, the thickness of the region and layer may be exaggerated. The same reference numerals in the drawings represent the same or similar structures, and thus detailed description thereof would be omitted.

The features, structures, or characteristics described above can be combined into one or more embodiments in any proper mode. In the description below, many specific details are provided to provide full understanding of the embodiments of this disclosure. However, a person skilled in the art would recognize that the technical solutions of this disclosure can be practiced without one or more of specific details or other methods, assemblies, materials, and the like can be adopted. Under other conditions, well-known structures, materials, or operations are not shown in detail to avoid blurring main technical creations of this disclosure.

Terms “one”, “a” and “the” are used for representing the existence of one or more elements/constitution parts/and the like; terms “comprise” and “have” are used for representing the open-type meaning of being included and refer to that additional elements/constitution parts/and the like may also exist except the listed elements/constitution parts/and the like. Terms “first” and “second” and the like are merely used for marking, rather than limiting the number of objects thereof.

In this disclosure, when describing the height of a structure, it refers to the size between an end of the structure away from the semiconductor substrate and the semiconductor substrate. When describing the top surface/top end of a structure, it refers to the surface/end of the structure away from the semiconductor substrate.

As the continuous decreasing of the manufacture procedure size, failures such as conductive plug disconnection would easily occur to the DRAM.

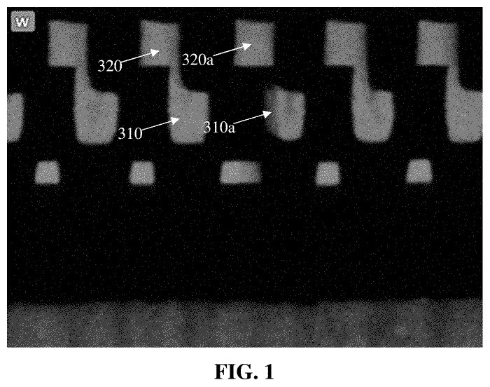

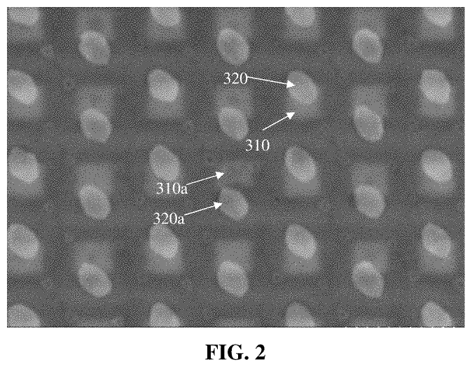

When manufacturing the wiring layer, failures such as conductive plug disconnection would easily occur. FIG. 1 is an electron micrograph of a cross-section of a wiring layer in some implementations. FIG. 2 is an electron micrograph taken in top view of a metal wiring layer in some implementations. As can be seen from FIG. 1 and FIG. 2, the conductive plug 310 is configured to be electrically connected to a contact pad 320. However, in FIG. 1 and FIG. 2, it can be further seen that a failure of disconnection occurs between the contact pad 320a and the conductive plug 310a.

The inventors of the present disclosure have recognized that, through a large number of researches and analysis on the failure, the failure is generated since the bitline structure extrudes the capacitance contact hole, rendering a contact area between the conductive plug and the contact pad in the capacitance contact hole to be reduced. However, as the continuous decreasing of the manufacture procedure size, it would be hard to improve the yield of the DRAM by reducing the size of the bitline structure because reducing the size of the bitline structure would cause the deep-width ratio of the bitline structure to be oversized to be easily collapsed.

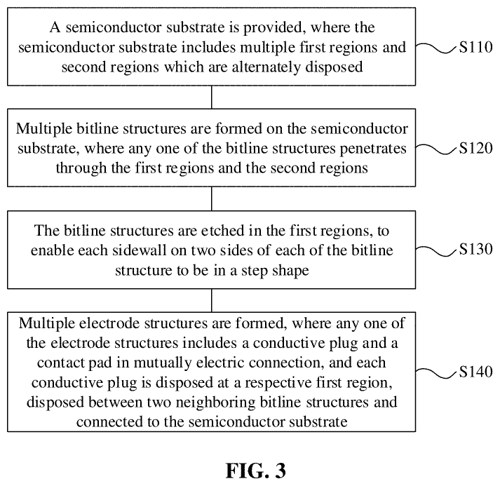

This disclosure provides a manufacturing method for a semiconductor structure. With reference to FIG. 3, the manufacturing method for a semiconductor structure may include the following operations.

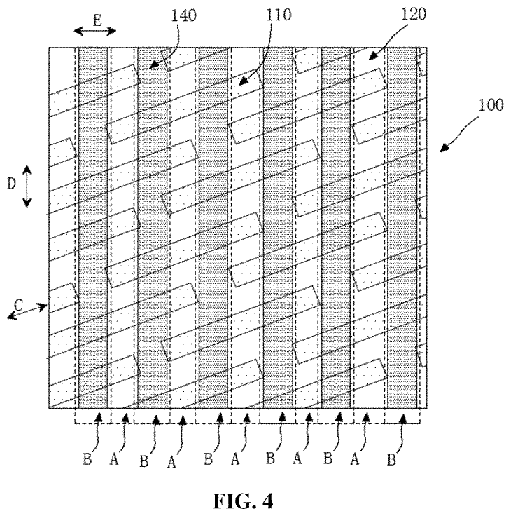

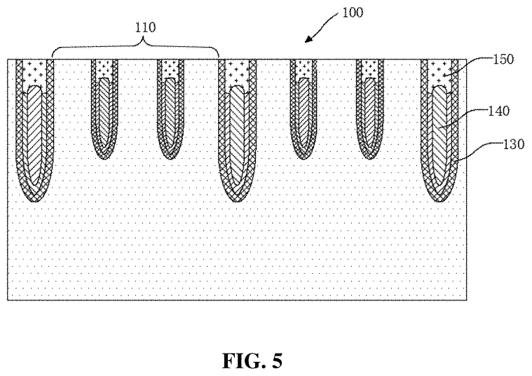

In S110, with reference to FIG. 4 and FIG. 5, a semiconductor substrate 100 is provided, and the semiconductor substrate 100 includes multiple first regions A and second regions B which are alternately disposed.

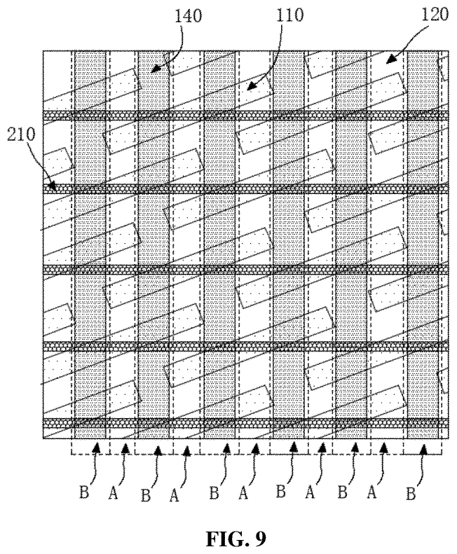

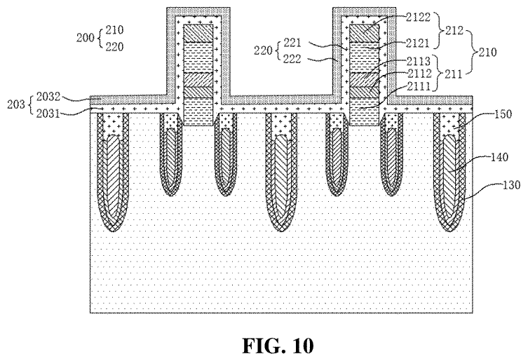

In S120, with reference to FIG. 9 and FIG. 10, multiple bitline structures 200 are formed on the semiconductor substrate 100, and any one of the bitline structures 200 penetrates through the first regions A and the second regions B.

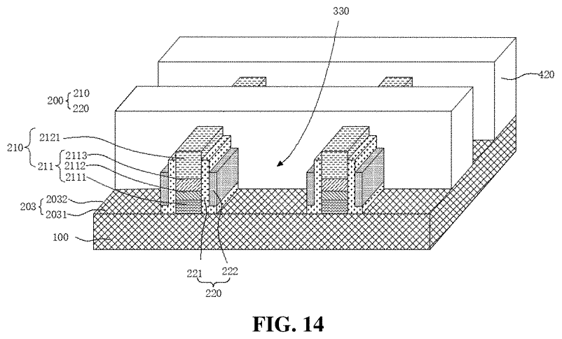

In S130, with reference to FIG. 14, the bitline structures 200 are etched in the first regions, to enable each sidewall on two sides of each of the bitline structure to be in a step shape.

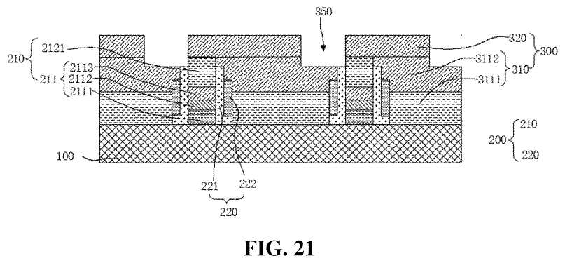

In S140, with reference to FIG. 21, multiple electrode structures 300 are formed, any one of the electrode structures 300 includes a conductive plug 310 and a contact pad 320 in mutually electric connection, and each conductive plug 310 is disposed at a respective first region A, disposed between two neighboring bitline structures 200 and connected to the semiconductor substrate 100.

According to the manufacturing method for a semiconductor structure provided by this disclosure, in S130, with reference to FIG. 14, the capacitance contact hole 330 for forming the conductive plug 310 can be manufactured; the capacitance contact hole 330 is disposed in the first regions A and disposed between two neighboring bitline structures 200. Since the step shape exists in the sidewall of the bitline structure 200 in the first regions A, the capacitance contact hole 330 presents characteristics of small bottom and large top, which can increase the size of the top of the capacitance contact hole 330, and prevent the conductive plug 310 from being broken by clamping due to the extrusion of the bitline structure on the top of the capacitance contact hole 330. Accordingly, in operation S140, with reference to FIG. 21, when forming the conductive plug 310, the size of the top of the conductive plug 310 can be larger, increasing the process window for manufacturing the conductive plug 310, preventing the conductive plug 310 from being disconnected due to etching in the manufacturing process, and ensuring the contact pad 320 to be electrically connected to the semiconductor substrate 100 through the conductive plug 310. In this way, the manufacturing method for a semiconductor structure of this disclosure can improve the manufacturing yield of the semiconductor structure, increase the process window of the semiconductor structure, and reduce the manufacturing cost of the semiconductor structure.

According to the manufacturing method for a semiconductor structure provided by this disclosure, with reference to FIG. 21, the manufactured semiconductor structure may include a semiconductor substrate 100, multiple bit line structures 200 and multiple electrode structures 300. With reference to FIG. 4, the semiconductor substrate 100 includes multiple first regions A and second regions B which are alternately disposed. Any one of the bitline structures 200 penetrates through the first regions A and the second regions B. In the first regions A, each sidewall on two sides of each of the bitline structure 200 is in a step shape. For the multiple electrode structures 300, any one of the electrode structures 300 includes a conductive plug 310 and a contact pad 320 in mutually electric connection, and the each conductive plug 310 is disposed at a respective first region A, disposed between two neighboring bitline structures 200 and connected to the semiconductor substrate 100. The semiconductor structure may be manufactured by the manufacturing method for a semiconductor structure, and therefore has same or similar technical effects, and the details are not repeated in this disclosure.

Further explanations and demonstrations of principles, details and effects of the manufacturing method for a semiconductor structure provided by this disclosure are further made by combining the accompanying drawings below.

In S110, a semiconductor substrate 100 can be provided. With reference to FIG. 4 and FIG. 5, the semiconductor substrate 100 has a sunken transistor and a wordline 140 buried therein, where the wordline 140 can be connected to a gate of the sunken transistor or be partially reused as a gate of the sunken transistor.

A material of the semiconductor substrate 100 may be selected from Si, Ge, SiGe, SiC, SiGeC, InAs, GaAs, InP, or other III/V compound semiconductors. It further includes a multi-layer structure formed by these semiconductors, or Silicon on Insulator (SOI), Stacked silicon on Insulator (SSOI), Stacked Silicon Germanium on Insulator (S-SIGEOI), Silicon Germanium on Insulator (SiGeOI) and Germanium on Insulator (GeOI), and the like. The semiconductor substrate 100 can be doped, for example, light doping can be performed on a part of the semiconductor substrate to form a channel of the sunken transistor; heavy doping can be performed on a part of the semiconductor substrate to enable the source or drain of the sunken transistor to be electrically connected to the bitline structure 200 and the electrode structure 300.

The semiconductor substrate 100 is provided with an isolation shallow trench so that multiple independent active regions 110 are formed on the semiconductor substrate 100; the isolation shallow trench can be filled with the dielectric to form the shallow trench isolation structure 120, for example, the isolation shallow trench can be filled with the dielectric such as silicon oxide. With reference to FIG. 4, the active regions 110 are arranged into multiple active region columns extending along a first direction C and parallel to each other; any one of the active region columns may include multiple active regions 110 and the extending direction of the active regions 110 is the first direction C.

The semiconductor substrate 100 is further provided with a wordline trench along a second direction D; an included angle between the second direction D and the first direction C is less than 90°. The wordline trench penetrates, along the second direction D, through the shallow trench isolation structure 120 and the active region 110 in sequence and exposes the semiconductor substrate 100 at the active region 110. In some embodiments, a doping dosage on the surface of the semiconductor surface 100 exposed by the wordline trench can further be adjusted, for example, by methods of ion injection and the like, increasing the doping dosage at the bottom of the wordline trench or injecting ions with opposite types, so as to further adjust the threshold voltage of the sunken transistor. In the wordline trench, it may include a gate dielectric layer 130 covering the sidewall of the wordline trench and a wordline 140 on an inner side of the gate dielectric layer 130. The gate dielectric layer 130 can be used as the gate insulation layer of the sunken transistor at the active region 110, and the wordline 140 may be partially reused as the gate of the sunken transistor. As can be understood that the gate dielectric layer 130 may be one layer of the insulation material, and may further be a composition of multiple layers of the insulation material, and air gaps may be packaged in the multiple layers of the insulation material; this disclosure does not define same. At the active region 110, a part of semiconductor substrate 100 corresponding to the wordline 140 may be the channel of the sunken transistor, and the part of the semiconductor substrate 100 connected to the channel may be used as the source and drain of the sunken transistor. The trench of the wordline 140 can be filled with the insulation material to form a dielectric top cover 150. The dielectric top cover 150 covers the wordline 140 so that the wordline 140 is embedded into the semiconductor substrate 100. Optionally, the surface of the semiconductor substrate 100 can further be provided with the insulation material to form a protection layer. The protection layer covers the semiconductor substrate 100 and protects the active region 110. In an embodiment of this disclosure, a material of the protection layer may be silicon nitride.

Optionally, the surface of the semiconductor substrate 100 may be heavily doped to ensure good conductivity of the source and drain of the sunken transistor, so as to ensure that the bitline structure 200 and the conductive plug 310 can be electrically connected to the source and drain of the sunken transistor.

In an embodiment of this disclosure, along the second direction D, every three active region columns relate to a period for periodical arrangement; along a third direction E vertical to the second direction D in a plane of the semiconductor substrate 100, the active region columns are periodically arranged. In other words, in the same active region column, the sum of the length of the active region 110 and a distance between two neighboring active regions 110 in the same active region column is a preset size; in the two neighboring active region columns, after a pattern of one active region column is translated to a neighboring active region column along the second direction D, the translated pattern of the active region column can be translated by ⅓ preset size along one specific direction in the first direction D, to be overlapped with the pattern of the active region 110 of the neighboring active region column. In the two neighboring active region columns, after a pattern of one active region column is translated to a neighboring active region column along the third direction E, the translated pattern of the active region column is overlapped with the pattern of the active region 110 of the neighboring active region column.

Optionally, any one active region 110 passes through two wordline trenches so that the two wordlines 140 pass through the active region 110. In this way, from the top view, the active region 110 is separated by the two wordlines 140 into a first contact region and a second contact region, where the second contact region is disposed between the two wordlines 140 penetrating through the active region 110 and the number of the first contact regions is two and the first contact regions are respectively disposed on two sides of the second contact region.

In the provided semiconductor substrate 100, it may include multiple first regions A and second regions B which are alternately disposed, where the extending directions of the first regions A and the second regions B are both the second direction D. In other words, the extending directions of the first regions A and the second regions B are both consistent with the extending direction of the wordline 140. The first regions A may include at least a part of the region of any one active region 110, and the second regions B may include at least a part of the region of any one active region 110. In the semiconductor substrate 100 provided by this disclosure, the second regions B are configured to form the dielectric barricade 420 for isolating each first region A; and the first region A is configured to form the capacitance contact holes 330 isolated by the bitline structure 200 and the dielectric barricade 420, these capacitance contact holes 330 are configured to, in S140, be filled with the conductive material and be patterned into the conductive plug 310.

Optionally, the second regions B are arranged in a one-to-one correspondence with the wordlines 140. Any one wordline 140 is in the corresponding second region B; and the first regions A are disposed between two neighboring wordlines 140.

Optionally, the following method can be used for manufacturing the semiconductor substrate 100.

In S210, a semiconductor substrate is provided. The semiconductor substrate 100 may be a P-type lightly doped monocrystalline silicon substrate or a P-type heavily doped monocrystalline silicon substrate.

In S220, an isolation to isolate multiple independent active regions 110 on the surface of the semiconductor substrate 100. Any one active region 110 extends along the first direction C.

In S230, the isolation shallow trench is filled with dielectric to form a shallow isolation structure 120, and the dielectric may be silicon oxide.

In S240, the semiconductor substrate 100 is etched to form a wordline trench extending along the second direction D; and the wordline trench penetrates through the shallow trench isolation structure 120 and the active region 110 in sequence.

In S250, the gate dielectric layer 130 covering the sidewall of the wordline trench is formed, and an inner side of the gate dielectric layer 130 is filled with the conductive structure to form the wordline 140.

In S260, the wordline trench is filled with dielectric to form a dielectric top cover 150 covering the wordline 140.

In this way, at the active region 110, the wordline 140 may be partially reused as the gate of the sunken transistor; the gate dielectric layer 130 may be partially reused as the gate insulation layer of the sunken transistor; and a part of the semiconductor substrate 100 neighboring the wordline 140 may be used as the channel of the sunken transistor. The sunken transistor and the wordline 140 are embedded in the semiconductor substrate 100.

In S120, multiple bitline structures 200 are formed on the semiconductor substrate 100, and any one of the bitline structures 200 penetrates through the first regions A and the second regions B. Optionally, the bitline structure 200 is a straight line and penetrates through each of the first regions A and second regions B in sequence. Furthermore, the bitline structure 200 extends along the third direction E, and the third direction E is vertical to the second direction D.

Optionally, the bitline structure 200 can be formed through S310 to S330 as follows.

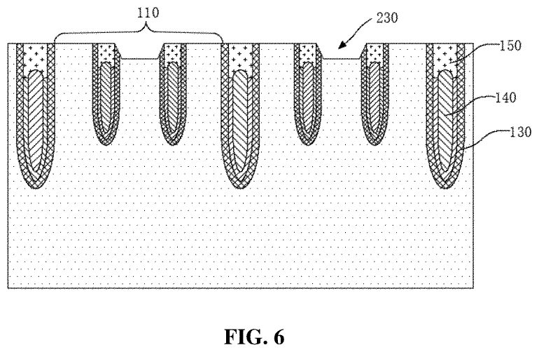

In S310, with reference to FIG. 6, a bitline contact trench 230 is etched on the semiconductor substrate 100, and the bitline contact trench 230 penetrates through each of the first regions A and the second regions B in sequence. The bitline contact trench 230 penetrates through each active region 110. Furthermore, the bitline contact trench 230 exposes the source or drain of the sunken transistor at the active region 110 so that the bitline structure 200 is connected to the source or drain of the sunken transistor.

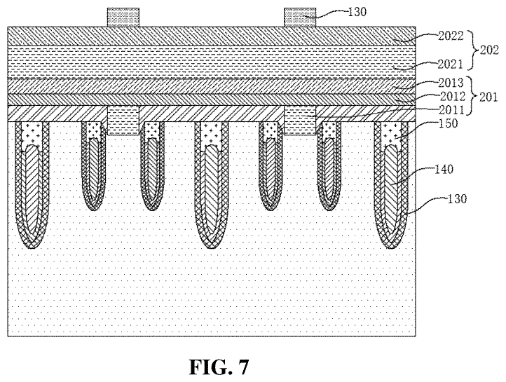

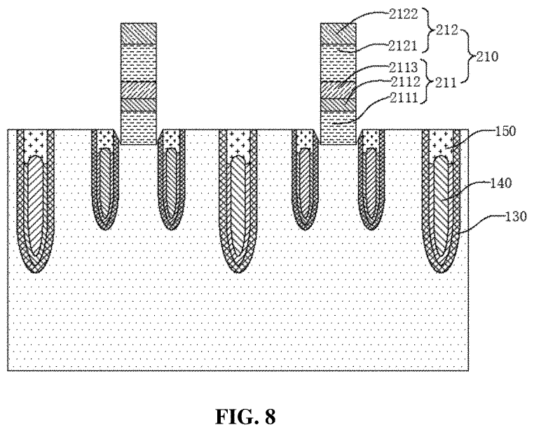

In S320, with reference to FIG. 7, the conductive materials and dielectric material can be deposited on the semiconductor substrate 100 in sequence to respectively form the conductive material layer 201 and the dielectric material layer 202. With reference to FIG. 8, the conductive material layer 201 and the dielectric material layer 202 are patterned to form the bitline lead 210, where a positive projection of the bitline lead 210 on the semiconductor substrate 100 is disposed in the bitline contact trench 230; the bitline lead 210 protrudes out of the bitline contact trench 230.

In S330, with reference to FIG. 10, at least one dielectric sidewall 220 is respectively formed on two sides of each of the bitline leads 210. In this way, the bitline structure 200 of this disclosure includes a bitline lead 210 and a dielectric sidewall 220 on two sides of the bitline lead.

Optionally, in S310, a photoetching process can be used for etching to remove a part of the active region 110 and a part of the shallow trench isolation structure 120 to form the bitline contact trench 230.

In an embodiment of this disclosure, in S310, the bitline contact trench 230 passes through the second contact region of the active region 110. Accordingly, with reference to FIG. 9, the bitline lead 210 passes through the second contact region of the active region 110.

In S320, the conductive material layer 201 may include one or more layers of the conductive material; these conductive materials may be selected from polysilicon, metal, alloy, conductive metal oxide, conductive metal nitride, conductive metal silicide, or other conductive materials. The conductive material layer 201 may be formed using the deposition method, for example, using the methods such as chemical vapor deposition, physical vapor deposition and atomic layer vapor deposition to form the conductive material layer 201; and the conductive material layer 201 is formed on the surface of the semiconductor substrate 100 to cover the bitline contact trench 230.

Exemplarily, in an embodiment of this disclosure, the conductive material layer 201 includes a first conductive material layer 2011, a second conductive material layer 2012 and a third conductive material layer 2013 disposed in a stack on the semiconductor substrate 100 in sequence. A material of the first conductive material layer 2011 can be the polycrystalline silicon material, in particular, the doped polycrystalline silicon material. A material of the second conductive material layer 2012 may be the conductive metal nitride and conductive metal silicide; for example, it may be titanium nitride or tungsten silicide. A material of the third conductive material layer 2013 can be a metal material, for example, it may be tungsten.

In S320, the dielectric material layer 202 may include one or more layers of the dielectric material; these dielectric materials may be selected from silicon oxide, silicon nitride, silicon oxynitride or other inorganic insulating materials. In an embodiment of this disclosure, the dielectric material layer 202 includes a first dielectric material layer 2021 and a second dielectric material layer 2022 disposed in a stack on the conductive material layer 201 in sequence, where the materials of the first dielectric material layer 2021 and the second dielectric material layer 2022 are different.

In an embodiment of this disclosure, the material of the first dielectric material layer 2021 is silicon nitride.

In an embodiment of this disclosure, the material of the second dielectric material layer 2022 is silicon oxide.

In S320, the photoetching process can be used for patterning the conductive material layer 201 and the dielectric material layer 202, so that the conductive material layer 201 is patterned as the conductive lead 211 and so that the dielectric material layer 202 is patterned as the dielectric protection layer 212 disposed on the conductive lead 211. In this way, the bitline lead 210 includes the conductive lead 211 and the dielectric protection layer 212 disposed on the conductive lead 211.

In an embodiment of this disclosure, the conductive lead 211 includes a first conductive lead layer 2111 formed by patterning the first conductive material layer 2011, a second conductive lead layer 2112 formed by patterning the second conductive material layer 2012 and a third conductive lead layer 2113 formed by patterning the third conductive material layer 2013; the dielectric protection layer 212 includes a first dielectric protection layer 2121 formed by patterning the first dielectric material layer 2021 and a second dielectric protection layer 2122 formed by patterning the second dielectric material layer 2022.

Optionally, in S330, the dielectric sidewall material layer 203 covering the surface of the conductive lead 211 and the surface of the semiconductor substrate 100 can be formed. The dielectric sidewall material layer 203 may include a first part covering the surface of the semiconductor substrate 100, a part covering the dielectric sidewalls 220 on both sides of the bitline lead 210, and a second part covering the top surface of the bitline lead 210. The first part and the second part can both be removed by using the photoetching process, and may also be reserved in S330 and removed in the subseIn Suent process.

Preferably, in S330, the dielectric sidewall material layer 203 is not patterned, i.e., the first part and the second part of the dielectric sidewall material 203 are reserved in S330.

In S330, since the bitline structure 200 includes at least one dielectric sidewall 220, in S130, each bitline lead 210 and its dielectric sidewalls 220 can be etched in the first regions A, so that the top ends of the dielectric sidewall 220 are disposed between a top end of the bitline lead 210 and the semiconductor substrate 100. In other words, in S330, by etching the bitline lead 210 and its dielectric sidewalls 220 in the first regions A, the capacitance contact hole 330 disposed between two neighboring bitline structures 200 in the first regions A can be enabled to present a shape with a small bottom end and a large top end.

In S330, a dielectric sidewall 220 may be formed and multiple layers of the dielectric sidewalls 220 may also be formed. When forming the multiple layers of the dielectric sidewalls 220, the materials for different layers of the dielectric sidewalls 220 may be different; in this way, in S140, the difference among etching speeds of different materials can be used for enabling the sidewalls on two sides of the bitline structure 200 to be in a step shape.

Preferably, in S330, at least two dielectric sidewalls 220 are respectively formed on two sides of each of the bitline leads 210. In this way, in S130, each bitline lead 210 and all its dielectric sidewalls 220 are etched in the first regions A, to enable a dielectric sidewall 220 adjacent to the bitline lead 210 among two neighboring dielectric sidewalls 220 has a greater height. In this way, the capacitance contact hole 330 disposed between the two neighboring bitline structures 200 in the first regions A can present the shape with an increased gradient from bottom to top, to further reduce the extrusion to the capacitance contact hole 330 by the bitline structure.

In an embodiment of this disclosure, with reference to FIG. 10, a first dielectric sidewall 221 and a second dielectric sidewall 222 can be formed in sequence, where the first dielectric sidewall 221 is disposed between the second dielectric sidewall 222 and the bitline lead 210. In this way, each bitline structure 200 includes a bitline lead 210 and the first dielectric sidewall 221 and the second dielectric sidewall 222 disposed on each side of the bitline lead 210. Optionally, the material of the first dielectric sidewall 221 is silicon nitride. Optionally, the material of the second dielectric sidewall 222 is silicon oxynitride.

Exemplarily, the first dielectric sidewall material layer 2031 covering the surface of the conductive lead 211 and the surface of the semiconductor substrate 100 can be formed, and the second dielectric sidewall material layer 2032 is formed on the surface of the first dielectric sidewall material layer 2031. In this way, each bitline structure 200 includes the first dielectric sidewall 221 and the second dielectric sidewall 222 disposed on the each side of the bitline lead 210. The top surface of the bitline structure 200 may be provided with the second part of the first dielectric sidewall material layer 2031 and the second part of the second dielectric sidewall material layer 2032 in sequence.

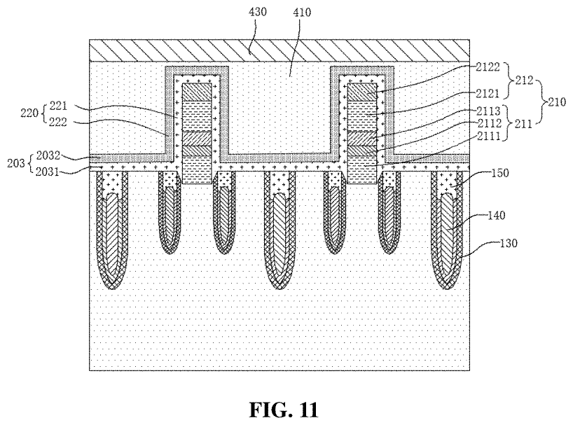

Optionally, the manufacturing method for a semiconductor structure provided by this disclosure may further includes the following operations: before S130, with reference to FIG. 11, the sacrificial dielectric material is filled among the bitline structures 200 in respective first regions A to form the sacrificial dielectric layer 410.

Optionally, the sacrificial dielectric material may be silicon oxide.

Optionally, the sacrificial dielectric material is filled among the bitline structures 200 through the method of deposition. Furthermore, the sacrificial dielectric material may be fully filled among the bitline structures 200, then through the chemical mechanical polishing (CMP) process, the deposited sacrificial dielectric material is planarized, to form the sacrificial dielectric layer 410 fully filling the respective gaps among the bitline structures 200.

according to the manufacturing method for a semiconductor structure provided in this disclosure, after forming the sacrificial dielectric layer 410, the capacitance contact hole 330 for receiving the conductive plug 310 can be manufactured in the first regions A and the dielectric barricade 420 can be manufactured in the second regions B. In some embodiments, the capacitance contact hole 330 may be formed first, or the conductive plug 310 may be formed first; then the dielectric barricade 420 is formed. In some other embodiments, the dielectric barricade 420 can be formed first, and then the capacitance contact hole 330 and the conductive plug 310 are formed.

Then, taking first forming the dielectric barricade 420 as an example, the method for forming the dielectric barricade 420 is introduced.

In this embodiment, the dielectric barricade 420 can be formed according to the method including S410 to S440.

In S410, a first mask structure 430 is formed on a side of the sacrificial dielectric layer 410 away from the semiconductor substrate 100. The first mask structure 430 may cover the first regions A and expose the sacrificial dielectric layer 410 in the second regions B. In some embodiments, the mask structure can further expose the bitline structure 200 in the second regions B.

In S420, the second regions B are etched to remove the exposed sacrificial dielectric material. In this way, the dielectric trench is formed in the second regions B.

In S430, the first mask structure 430 is removed.

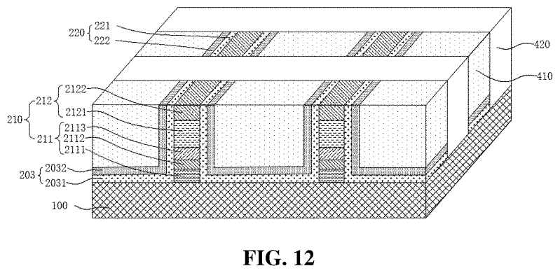

In S440, with reference to FIG. 12, the dielectric trench is filled with the dielectric material to form a dielectric barricade 420.

In S410, the first mask structure 430 may include a mask layer, and may also include multiple mask layers, so as to effectively expose the second regions B and protect the first regions A.

In S420, the first mask structure 430 can be used as a mask so that the second regions B are etched to remove the exposed sacrificial dielectric material.

Furthermore, in the second regions B, when etching to remove the sacrificial dielectric material, a part of the bitline structure 200 may also be etched, for example, a part of the dielectric sidewall 220, a part of the dielectric protection layer 212, and the like of the bitline structure 200 may be etched. Moreover, if the top surface of the bitline structure 200 is provided with the second part of the dielectric sidewall material layer 203, the second part of the dielectric sidewall material layer 203 can also be etched.

For example, in an embodiment of this disclosure, in the second regions B, before forming the dielectric trench, each bitline structure 200 includes the bitline lead 210 and the first dielectric sidewall 221 and the second dielectric sidewall 222 disposed on each side of the bitline lead 210. The bitline structure 200 includes the first conductive lead layer 2111, the second conductive lead layer 2112, the third conductive lead layer 2113, the first dielectric protection layer 2121, and the second dielectric protection layer 2122 stacked in sequence. The top surface of the bitline structure 200 is further provided with the second part of the first dielectric sidewall material layer 2031 and the second part of the second dielectric sidewall material layer 2032 in sequence. After etching the second regions B to form the dielectric trench, in the second regions B, the second part of the first dielectric sidewall material layer 2031 and the second part of the second dielectric sidewall material layer 2032 are removed; the second dielectric protection layer 2122 is removed; a part of the first dielectric protection layer 2121 is removed; parts of the upper parts of the first dielectric sidewall 221 and the second dielectric sidewall 222 are both removed.

In S440, the dielectric trench can be filled with the dielectric material by using the method of deposition; the dielectric material filled in the dielectric trench is mutually embedded with the bitline structure 200 in the second regions B, so as to enable two neighboring first regions A are isolated through the dielectric barricade 420.

Optionally, the dielectric material filled in the dielectric trench may be silicon nitride to improve the isolation performance of the dielectric barricade 420 and reduce the parasitic capacitance between two neighboring conductive plugs 310.

Optionally, after the dielectric trench is filled with the dielectric material, the redundant dielectric material can be removed through the CMP process. In some embodiments, in the CMP process, the entire substrate further be thinned, so as to expose the sacrificial dielectric layer 410 in the first regions A, and to expose the bitline lead 210.

As can be understood that, the embodiment above is only a method embodiment for forming the dielectric barricade 420; in the embodiments of this disclosure, other methods can also be used for forming the dielectric barricade 420, but are not described in this disclosure in detail.

In S130, the bitline structures 200 are etched in the first regions, so that sidewalls of two sides of each of the bitline structure 200 are all in a step shape. Optionally, the bitline structures 200 include bitline leads 210 and the dielectric sidewall 220 on the side of the bitline leads 210. In the first regions A, the bitline leads 210 and the dielectric sidewall 220 are etched; after etching, a top end of the dielectric sidewall 220 is disposed between the top surface of the bitline leads 210 and the semiconductor substrate 100.

Optionally, according to the materials of the bitline leads 210 and the dielectric sidewall 220, selective etching can be performed under different etching conditions, so that the height of the bitline leads 210 is different from the height of the dielectric sidewall 220.

Exemplarily, in an embodiment of this disclosure, before S130, in the first regions A, the bitline structure 200 includes a bitline lead 210 and the first dielectric sidewall 221 and the second dielectric sidewall 222 disposed on the side of the bitline lead 210. The bitline lead 210 includes the conductive lead 211, the first dielectric protection layer 2121 and the second dielectric protection layer 2122 disposed in a stack. In the first regions A, the sacrificial dielectric material is filled between the two neighboring bitline structures 200, i.e., already a sacrificial dielectric layer 410 has been formed, the sacrificial dielectric material is the same as the material of the second dielectric protection layer 2122, i.e., the same as the material of the second dielectric material layer 2022. In the first regions A, the sacrificial dielectric layer 410 and the second dielectric protection layer 2122 can be exposed, i.e., before S130, the sacrificial dielectric layer 410 and the second dielectric protection layer 2122 in the first regions A can be exposed through etching, CMP, or other methods.

In S130, the following two selective etchings can be used for etching the first regions A.

For the first etching: the first regions A are etched under a first etching condition, so that an etching speed of the second dielectric material layer 2022 to be less than an etching speed of the second dielectric sidewall 222 that is less than an etching speed of the first dielectric sidewall 221.

For the second etching, the first regions A are etched under a second etching condition, so that an etching speed of the sacrificial dielectric layer 410 to be greater than the etching speed of the second dielectric sidewall 222 that is greater than the etching speed of the first dielectric sidewall 221, so as to completely remove the sacrificial dielectric layer disposed in the first regions A.

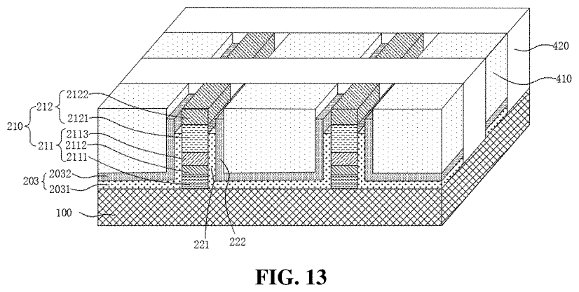

In the process of the first etching, with reference to FIG. 13, since the second dielectric material layer 2022 has the lowest etching speed under the first etching condition, the second dielectric protection layer 2122 can protect the first dielectric protection layer 2121 to prevent the first dielectric protection layer 2121 from being etched in the process of the first etching; accordingly, the sacrificial dielectric layer 410 disposed in the first regions A can also be reserved due to the slow etching speed. The etching speed of the second dielectric sidewall 222 is less than the etching speed of the first dielectric sidewall 221, so that the top of the second dielectric sidewall 222 is higher than the first dielectric sidewall 221.

In the first etching, an etching time can be controlled to adjust the etching depth of each structure. Preferably, after the first etching, the height of the top surface of the first dielectric sidewall 221 is lower than the height of the top surface of the second dielectric protection layer 2122, so as to ensure that, after the second etching, the height of the top surface of the first dielectric sidewall 221 is lower than the height of the top surface of the second dielectric protection layer 2122.

In the process of the second etching, with reference to FIG. 14, since the second dielectric material layer 2022 has the largest etching speed under the second etching condition, the second dielectric protection layer 2122 can be completely removed. Accordingly, the sacrificial dielectric layer 410 disposed in the first regions A can thus also be completely removed due to the larger etching speed. The etching speed of the second dielectric sidewall 222 is greater than the etching speed of the first dielectric sidewall 221, so that the top of the second dielectric sidewall 222 is lower than the first dielectric sidewall 221. Due to the protection of the second dielectric protection layer 2122 at the starting stage, it can be ensured that the height of the top surface of the first dielectric sidewall 221 is lower than the height of the top surface of the first dielectric protection layer 2121.

Optionally, the material of the second dielectric material layer 2022 and the material of the sacrificial dielectric material are both silicon oxide; the material of the first dielectric sidewall 221 is silicon nitride; the material of the second dielectric sidewall 222 is silicon oxynitride. The more the content of the oxide in the dielectric material, the smaller the etching speed of the dielectric material is under the first etching condition and the larger the etching speed under the second etching condition; the less the content of the oxide in the dielectric material, the larger the etching speed of the dielectric material is under the first etching condition and the smaller the etching speed under the second etching condition.

Optionally, in S130, when etching the first regions A, the second regions B do not need to be protected. In other words, even if the etching process of S130 thins the dielectric in the second regions B, the performances of the second regions B would not be changed. Exemplarily, the dielectric barricade 420 is formed in the second regions B, and in S130, the first regions A and the second regions B can be etched simultaneously, so that the height of the dielectric barricade 420 in the second regions B is lowered.

Optionally, in S130, when etching the first regions A, after removing the sacrificial dielectric layer 410, etching can further be continued, so as to remove the first part of the dielectric sidewall material layer 203 for exposing the semiconductor substrate 100, in particular, exposing the source or drain of the active region 110.

As a specific embodiment, S120 to S130 can be implemented according to the following method.

In S120, a conductive material layer 201, a first dielectric material layer 2021, and a second dielectric material layer 2022 are deposited on the semiconductor substrate 100 in sequence, and then the conductive material layer 201, the first dielectric material layer 2021, and the second dielectric material layer 2022 are patterned to form the bitline leads 210, the bitline leads 210 penetrates through the first regions A and the second regions B, where the material of the second dielectric material layer 2022 is silicon oxide.

A first dielectric sidewall 221 and a second dielectric sidewall 222 are formed on each of two sides of each of the bitline leads 210 in sequence, where the material of the first dielectric sidewall 221 is silicon nitride and the material of the second dielectric sidewall 222 is silicon oxynitride.

Before S130, the manufacturing method for a semiconductor structure further includes:

after forming the multiple bitline structures 200, a sacrificial dielectric material is filled among the bitline structures 200 to form a sacrificial dielectric layer 410, the sacrificial dielectric material is the same as the material of the second dielectric material layer 2022; and

the sacrificial dielectric layer 410 in the respective first regions A is removed and silicon nitride is filled among the bitline structures in the respective second regions.

In operation S130:

the first regions A are etched under a first etching condition, so that an etching speed of silicon oxide to be less than an etching speed of silicon oxynitride that is less than an etching speed of silicon nitride; and

the first regions A are etched under a second etching condition, so that the etching speed of silicon oxide to be greater than the etching speed of silicon oxynitride that is greater than the etching speed of silicon nitride, so as to completely remove the sacrificial dielectric layer 410 disposed in the first regions A.

In S140, multiple electrode structures 300 can be formed, any one of the electrode structures 300 includes a conductive plug 310 and a contact pad 320 in mutually electric connection, and each conductive plug 310 is disposed at a respective first region A, disposed between two neighboring bitline structures 200 and connected to the semiconductor substrate 100.

Optionally, the electrode structure 300 can be formed through the method shown in S510 to S530.

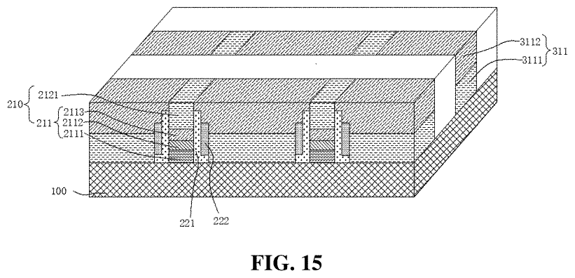

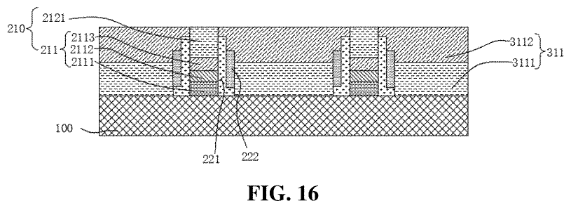

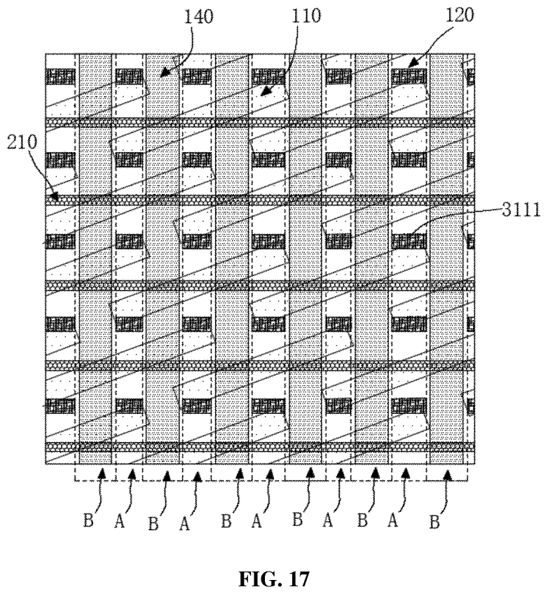

In S510, with reference to FIG. 15 to FIG. 17, a conductive material is filled between two neighboring bitline structures 200 in the first regions A to form a plug material layer 311.

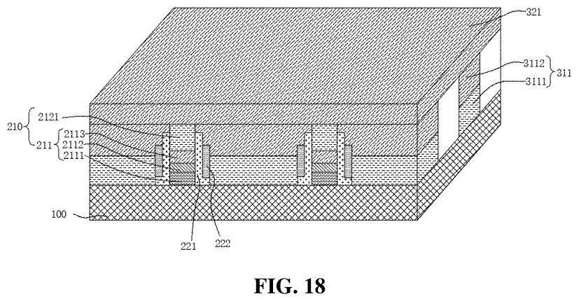

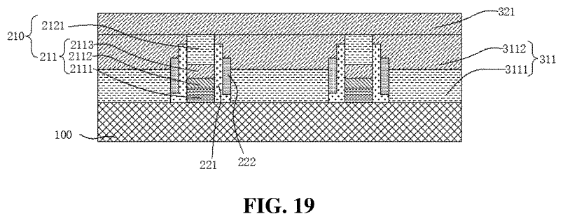

In S520, with reference to FIG. 18 and FIG. 19, a contact pad material layer 321 covering the plug material layer 311 is formed.

In S530, with reference to FIG. 21, the plug material layer 311 and the contact pad material layer 321 are patterned, so that the contact pad material layer 321 is patterned into the multiple contact pads 320, and so that the plug material layer 311 is patterned into the multiple conductive plugs 310.

In S510, polycrystalline silicon and a metal material are filled in sequence between the two neighboring bitline structures 200 in the first regions A, and the metal material may be crane. Then, planarization can be performed through the CMP process, to obtain the plug material layer 311; the plug material layer 311 includes a polycrystalline silicon layer 3111 and a metal layer 3112 disposed in a stack, and filled in the capacitance contact hole 330 defined by the bitline structure 200 and the dielectric barricade 420.

Preferably, with reference to FIG. 14 and FIG. 15, before S510, the dielectric barricades 420 are formed in respective second regions B. In S510, in the CMP process, the surface of the entire substrate can be flushed, in particular, enabling the dielectric barricades 420 to be flushed with the second regions B. In this way, a planarization surface can be provided for the contact pad material layer 321.

In S520, a metal material can be deposited on the entire substrate, to form a contact pad material layer 321 covering the plug material layer 311. Optionally, the material of the contact pad material layer 321 may be the same as the material of the top of the plug material layer 311, for example, may both be crane.

As can be understood, in S520, the material of the contact pad material layer 321 may further cover the second regions B already formed with the dielectric barricade 420.

In S530, with reference to FIG. 21, the plug material layer 311 and the contact pad material layer 321 can be etched to form isolation grooves 350; the isolation grooves 350 penetrate through the contact pad material layer 321 so that the contact pad material layer 321 is patterned into multiple separated contact pads 320; and bottom surfaces of the isolation grooves 350 are disposed at the plug material layer 311 and not lower than top surfaces of sidewalls of respective bitline structures 200.

In the embodiment, a part of the plug material layer 311 above the top surface of the sidewall of the bitline structure 200 has the largest size; when the part is etched to form an isolation grooves 350, it would not be easier to enable the part to be completely etched, thereby causing the contact pad 320 not to be electrically connected to the active region 110. As compared with the prior art, in this disclosure, the size of an upper end of the plug material layer 311 and only etches the enlarged upper end part, so as to avoid disconnection by etching the plug material layer 311 during the etching process to cause the disconnection between the contact pad 320 and the active region 110, which can improve the yield of the semiconductor structure.

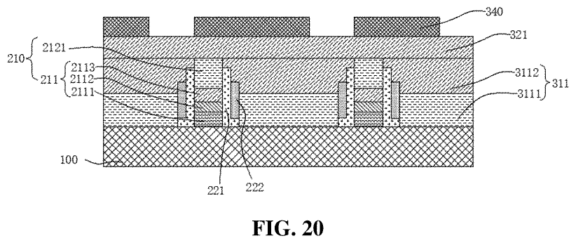

In some embodiments, with reference to FIG. 20, a second mask structure 340 can be formed on a side of the contact pad material layer 321 away from a back plate; the second mask structure 340 covers a region to be formed into the contact pad 320 and exposes other regions; then etching is performed to form the contact pad 320 and continuous etching is performed to etch the plug material layer 311 to form the isolation grooves 350 for isolating each contact pad 320.

In an embodiment of this disclosure, when patterning the contact pad material layer 321, the contact pad 320 may be enabled to present a diamond shaped with a chamfer Certainly, in other embodiments, the contact pad 320 can be enabled to have other shapes, for example, enabling the contact pad 320 to be round.

In an embodiment of this disclosure, in S530, the contact pad material layer 321 can be patterned to form the multiple contact pads 320 densely arranged and each having an orthohexagonal shape. In other words, a connection line of centers of three neighboring contact pads 320 can be an equilateral triangle; at a non-edge position, one contact pad 320 is neighboring six contact pads 320 and the connection line of centers of the six contact pads 320 neighboring the contact pad 320 present a regular hexagon.

It is to be explained that each operation in the method of this disclosure is described in a specific order in the accompanying drawings; however, this does not request or imply that the steps are executed according to the specific order, or all shown operations are necessarily executed so as to implement a desired result. Additionally, or alternatively, some operations may be omitted; multiple operations are combined into one operation to be executed, and/or one operation may be divided into multiple operations to be executed; which should all be considered as a part of this disclosure.

This disclosure further provides a semiconductor structure. With reference to FIG. 21, the semiconductor structure includes a semiconductor substrate 100, multiple bitline structures 200, and multiple electrode structures 300. With reference to FIG. 4, the semiconductor substrate 100 includes multiple first regions A and second regions B which are alternately disposed. With reference to FIG. 14 and FIG. 9, any one of the bitline structures 200 penetrates through the first regions A and the second regions B. In the first regions A, the sidewalls of the two sides of each of the bitline structures 200 are all in a step shape. With reference to FIG. 21, any one of the electrode structures 300 includes a conductive plug 310 and a contact pad 320 in mutually electric connection, and each conductive plug is disposed at a respective first region A, disposed between two neighboring bitline structures 200 and connected to the semiconductor substrate 100.

The semiconductor structure provided by this disclosure may be manufactured by means of embodiments of the manufacturing method for a semiconductor structure, and therefore has same or similar technical features, for example, having a higher manufacturing yield, and the like, and the details are not repeated in this disclosure. Other details and features of the semiconductor structure provided by this disclosure are recited in the embodiments of the manufacturing method for a semiconductor structure above or can be reasonably inferred according to the contents recited in the embodiments of the manufacturing method for a semiconductor structure above, and the details are not repeated in this disclosure.

Exemplarily, in an embodiment of this disclosure, with reference to FIG. 14, each bitline structure 200 includes the bitline lead 210 and at least one dielectric sidewall 220 respectively disposed on two sides of each of the bitline leads 210; and in the first regions A, top ends of the dielectric sidewalls 220 are disposed between a top end of the bitline lead 210 and the semiconductor substrate 100.

Exemplarily, in an embodiment of this disclosure, with reference to FIG. 14, each bitline structures 200 include the bitline lead 210 and at least two dielectric sidewalls 220 respectively disposed on two sides of each of the bitline leads 210; and in the first regions A, a dielectric sidewall 220 adjacent to the bitline lead 210 among two neighboring dielectric sidewalls 220 has a greater height.

Exemplarily, in an embodiment of this disclosure, with reference to FIG. 21, an isolation groove 350 formed among two neighboring electrode structures 300; and bottom surfaces of the isolation grooves 350 are not lower than top surfaces of sidewalls of respective bitline structures 200.

Exemplarily, in an embodiment of this disclosure, the contact pads 320 are densely arranged and each having an orthohexagonal shape.

The embodiments of this disclosure further provide a storage device. The storage device includes any one storage device described by the embodiments of the semiconductor structure. The storage device may be Dynamic Random-Access Memory (DRAM) or other types of storage devices. The storage device includes any one storage device described by the embodiments of the semiconductor structure, and therefore has the same beneficial effect, and the details are not repeated in this disclosure.

As can be understood, this disclosure does not limit its application to the detailed structure and arranging modes of the parts proposed in this specification. This disclosure can have other embodiments and can be implemented and performed in multiple modes. The preceding deformation modes and amendment modes fall within the scope of this disclosure. As can be understood, this specification discloses and limit all replaceable combinations of two or more separate features which are mentioned or apparent in the text and/or drawings extended by this disclosure. All of these different combinations constitute multiple replaceable aspects of this disclosure. The embodiments of this specification explain the well-known optimal mode for implementing this disclosure and enable a person skilled in the art can use this disclosure.

What is claimed is:

1. A manufacturing method for a semiconductor structure, comprising:
providing a semiconductor substrate, wherein the semiconductor substrate comprises a plurality of first regions and second regions which are alternately disposed;
forming a plurality of bitline structures on the semiconductor substrate, wherein any one of the bitline structures penetrates through the first regions and the second regions;
etching the bitline structures in the first regions, to enable each sidewall on two sides of each of the bitline structure to be in a step shape; and
forming a plurality of electrode structures, wherein any one of the electrode structures comprises a conductive plug and a contact pad in mutually electric connection, and each conductive plug is disposed at a respective first region, disposed between two neighboring bitline structures and connected to the semiconductor substrate.

2. The manufacturing method for a semiconductor structure of claim 1, wherein forming the plurality of bitline structures on the semiconductor substrate comprises:
forming a plurality of bitline leads on the semiconductor substrate, wherein any one of the bitline leads penetrates through the first regions and the second regions; and
forming at least one dielectric sidewall respectively on two sides of each of the bitline leads; and
etching the bitline structures in the first regions comprises:
etching each bitline lead and its dielectric sidewalls in the first regions, to enable top ends of the dielectric sidewalls to be disposed between a top end of the bitline lead and the semiconductor substrate.

3. The manufacturing method for a semiconductor structure of claim 2, wherein forming the at least one dielectric sidewall respectively on two sides of each of the bitline leads comprises:
forming at least two dielectric sidewalls respectively on two sides of each of the bitline leads; and
the etching the bitline structures in the first regions comprises:
etching, in the first regions, each bitline lead and all its dielectric sidewalls, to enable a dielectric sidewall adjacent to the bitline lead among two neighboring dielectric sidewalls has a greater height.

4. The manufacturing method for a semiconductor structure of claim 1, wherein forming the plurality of bitline structures on the semiconductor substrate comprises:
depositing a conductive material layer, a first dielectric material layer and a second dielectric material layer on the semiconductor substrate in sequence, and then patterning the conductive material layer, the first dielectric material layer and the second dielectric material layer to form the bitline leads; and
forming a first dielectric sidewall and a second dielectric sidewall on each of two sides of each of the bitline leads in sequence;
wherein the manufacturing method for a semiconductor structure further comprises:
filling a sacrificial dielectric material among the bitline structures to form a sacrificial dielectric layer, wherein the sacrificial dielectric material is the same as a material of the second dielectric material layer; and
etching the bitline structures in the first regions comprises:
etching the first regions under a first etching condition, to enable an etching speed of the second dielectric material layer to be less than an etching speed of the second dielectric sidewall that is less than an etching speed of the first dielectric sidewall; and
etching the first regions under a second etching condition, to enable an etching speed of the sacrificial dielectric layer to be greater than the etching speed of the second dielectric sidewall that is greater than the etching speed of the first dielectric sidewall, so as to completely remove the sacrificial dielectric layer disposed in the first regions.

5. The manufacturing method for a semiconductor structure of claim 4, wherein a material of the second dielectric material layer and the sacrificial dielectric material are both silicon oxide; a material of the first dielectric sidewall is silicon nitride; and a material of the second dielectric sidewall is silicon oxynitride.

6. The manufacturing method for a semiconductor structure of claim 1, wherein forming the plurality of electrode structures comprises:
filling a conductive material between two neighboring bitline structures in the first regions to form a plug material layer;
forming a contact pad material layer covering the plug material layer; and
patterning the plug material layer and the contact pad material layer, to enable the contact pad material layer to be patterned into a plurality of the contact pads, and to enable the plug material layer to be patterned into a plurality of the conductive plugs.

7. The manufacturing method for a semiconductor structure of claim 6, wherein patterning the plug material layer and the contact pad material layer comprises:
etching the plug material layer and the contact pad material layer to form isolation grooves, wherein the isolation grooves penetrate through the contact pad material layer to enable the contact pad material layer to be patterned into a plurality of separated contact pads, and bottom surfaces of the isolation grooves are disposed at the plug material layer and not lower than top surfaces of sidewalls of respective bitline structures.

8. The manufacturing method for a semiconductor structure of claim 1, wherein patterning the plug material layer and the contact pad material layer comprises:
patterning the contact pad material layer to form a plurality of the contact pads densely arranged and each having an orthohexagonal shape.

9. The manufacturing method for a semiconductor structure of claim 1, wherein
forming the plurality of bitline structures on the semiconductor substrate comprises:
depositing a conductive material layer, a first dielectric material layer and a second dielectric material layer on the semiconductor substrate in sequence, and then patterning the conductive material layer, the first dielectric material layer and the second dielectric material layer to form the bitline leads, the bitline leads penetrating through the first regions and the second regions, wherein a material of the second dielectric material layer is silicon oxide; and
forming a first dielectric sidewall and a second dielectric sidewall on each of two sides of each of the bitline leads in sequence, wherein a material of the first dielectric sidewall is silicon nitride and a material of the second dielectric sidewall is silicon oxynitride;
the manufacturing method for a semiconductor structure further comprises:
after forming the plurality of bitline structures, filling a sacrificial dielectric material among the bitline structures to form a sacrificial dielectric layer, wherein the sacrificial dielectric material is the same as a material of the second dielectric material layer; and
removing the sacrificial dielectric layer in the respective first regions and filling silicon nitride among the bitline structures in the respective first regions; and
etching the bitline structures in the first regions comprises:
etching the first regions under a first etching condition, to enable an etching speed of silicon oxide to be less than an etching speed of silicon oxynitride that is less than an etching speed of silicon nitride; and
etching the first regions under a second etching condition, to enable the etching speed of silicon oxide to be greater than the etching speed of silicon oxynitride that is greater than the etching speed of silicon nitride, so as to completely remove the sacrificial dielectric layer disposed in the first regions.

10. A semiconductor structure, comprising:
a semiconductor substrate, comprising a plurality of first regions and second regions which are alternately disposed;
a plurality of bitline structures, wherein any one of the bitline structures penetrates through the first regions and the second regions; and in the first regions, each sidewall on two sides of each of the bitline structure is in a step shape; and
a plurality of electrode structures, wherein any one of the electrode structures comprises a conductive plug and a contact pad in mutually electric connection, and each conductive plug is disposed at a respective first region, disposed between two neighboring bitline structures and connected to the semiconductor substrate.

11. The semiconductor structure of claim 10, wherein each of the bitline structures comprises a bitline lead and at least one dielectric sidewall respectively disposed on two sides of each of the bitline leads; and in the first regions, top ends of the dielectric sidewalls are disposed between a top end of the bitline lead and the semiconductor substrate.

12. The semiconductor structure of claim 11, wherein each bitline structure comprises the bitline lead and at least two dielectric sidewalls respectively on two sides of each of the bitline leads; and in the first regions, a dielectric sidewall adjacent to the bitline lead among two neighboring dielectric sidewalls has a greater height.

13. The semiconductor structure of claim 10, wherein an isolation groove is formed among two neighboring electrode structures, wherein bottom surfaces of the isolation grooves are not lower than top surfaces of sidewalls of respective bitline structures.

14. The semiconductor structure of claim 10, wherein the contact pads are densely arranged and each having an orthohexagonal shape.

15. A storage device, comprising the semiconductor structure of claim 10.
